(19) United States
(12) Patent Application Publication
(10) Pub. No.: US 2005/0236033 A1
(43) Pub. Date: Oct. 27, 2005

(54) Plasmon enhanced sensitized photovoltaic cells

(76) Inventor: Nabil M. Lawandy, Saunderstown, RI (US)

Correspondence Address: KIRKPATRICK & LOCKHART NICHOLSON GRAHAM LLP;(FORMERLY KIRKPATRICK & LOCKHART LLP), 75 STATE STREET, BOSTON, MA, 02109-1808, US

(21) Appl. No.: 11/104,873

(22) Filed: Apr. 13, 2005

Related U.S. Application Data
(60) Provisional application No. 60/602,411, filed on Aug. 18, 2004.
(60) Provisional application No. 60/561,867, filed on Apr. 13, 2004.

(51) Int. Cl. H01L 31/00; G01N 21/55

(52) U.S. Cl. 136/252; 136/256

(57) ABSTRACT

A plasmon enhanced particle for use in a photovoltaic cell. The particle includes a nanostructure capable of plasmon resonance; a charge accepting semiconductor in conjunction with the nanostructure; and a sensitizer coating the charge accepting semiconductor. Another aspect the invention relates to a plasmon enhanced solar photovoltaic cell. The solar photovoltaic cell includes a plurality of nanoparticles capable of plasmon resonance; a plurality of nanoparticles of charge accepting semiconductor in conjunction with the nanoparticles capable of plasmon resonance; and a coating of sensitizer on the plurality of nanoparticles of charge accepting semiconductor. Another aspect relates to a method of making a plasmon enhanced material suitable for use in a photovoltaic cell. The steps include providing a nanostructure capable of plasmon resonance; providing a charge accepting semiconductor in conjunction with the nanostructure; sintering the charge accepting semiconductor such as metal oxide; and coating the charge accepting semiconductor with sensitizer.

### RELATED APPLICATIONS

This application claims the benefit under 35 U.S.C. § 119(e) to U.S. Provisional Application No. 60/602,411 filed Aug. 18, 2004 and entitled “METALLIC CORE SEMICONDUCTOR STRUCTURE FOR IMPROVED CATALYSIS AND SOLAR CELL PERFORMANCE” and to U.S. Provisional Application No. 60/561,867 filed Apr. 13, 2004 and entitled “PLASMON ENHANCED DYE SENSITIZED SOLAR CELLS,” the entire disclosures of each of which are hereby incorporated herein by reference for all purposes.

### FIELD OF THE INVENTION

The invention relates to photovoltaic cells, and more specifically to sensitized photovoltaic cells.

### BACKGROUND OF THE INVENTION

The development of dye sensitized solar cells by Gratzel has opened the door to a new ultra-low cost photovoltaic cell technology. The Gratzel type solar cells rely on the use of anatase TiO₂ and organic dyes, such as ruthenium dye, to absorb visible light and provide charge injection. For example, the TiO₂ or ZnO used in such cells are typically in nanocrystaline form and coated with organic dyes on the surface. A diagram of such a nanocrystalline photovoltaic cell, such as a Gratzel cell, is shown in FIG. 1 and discussed in more detail below. The lowest portion of the diagram depicts the nanocrystaline porous composite created by deposition of TiO₂ particles, such as Degussa P25 (Degussa AG, Dusseldorf, Germany), and subsequent sintering, i.e., to establish electrical conductivity. Following this step, the surface of the TiO₂ matrix is coated with sensitizer compounds such as dyes, other smaller bandgap semiconductor nanocrystals or quantum dots. The material is then used in the photovoltaic cell structure.

A plasmon is a density wave of charge carriers which form at the interface of a conductor and a dielectric. Plasmons determine, to a degree, the optical properties of conductors, such as metals. Plasmons at a surface interact strongly with photons of light, forming a polariton. Localized surface plasmons have been observed since the time of the Romans, who used gold and silver nanoparticles to create colored glass objects such as the Lycurgus Cup (4th Century A.D.). A gold sol in the British museum, created by Michael Faraday in 1857, is still exhibiting its red color due to the plasmon resonance at ˜530 nm. In more recent times, localized plasmons have been observed on rough surfaces and in engineered nanostructures.

Localized surface plasmon resonances are associated with giant enhancements of field amplitudes in spatial regions near particles which generate plasmons. For example, gold nanoparticles exhibit the well known Tyndal resonance. Such particles exhibit a large absorption in the green region of the visible light spectrum, which results in the gold colloid appearing red. The field inside and at the surface of the gold nanoparticle in this case is enhanced by several orders of magnitude. This field enhancement is only limited by the complex dielectric response, which remains after the resonance is created when the real parts of the dielectric function approach zero.

For a metallic particle in a medium with index of refraction of unity, the plasmon resonance occurs at ωᵣ˜0.58 ωₚ, where ωₚ is the bulk plasmon frequency of the metal. The field enhancement occurs very near the particle and decays rapidly, typically as 1/R³ for the dipolar limit where R is the distance from the center of the plasmon supporting structure. The field enhancement is also a function of the angular coordinates around the particle. The field enhancement may be realized in aggregates and other shapes such as rods, cubes, and triangles, as well as composite core-shell versions of all of these. Changing the shape of the particles or using layered structures of metals and dielectrics may be used to tune the plasmon, as well as changing material response properties of the compound by changing, for example, from gold to silver, etc.

The enhancement of the local fields may result in enhanced optical properties ranging from the absorption of resonant light to a variety of nonlinear phenomena. The enhancement of absorption requires that the plasmon resonance be tuned to or near the absorption resonance of the material of interest and that the absorbing material be placed near the particles exhibiting the plasmon.

The present invention addresses the use of plasmon resonance to increase the efficiency of sensitized photovoltaic cells.

### SUMMARY OF THE INVENTION

In one aspect, the invention relates to a plasmon enhanced particle suitable for use in a photovoltaic cell. The particle includes a nanostructure capable of plasmon resonance; a charge accepting semiconductor in conjunction with the nanostructure; and a sensitizer such as a dye, smaller band-gap semiconductor nanocrystals or quantum dots coating the charge accepting semiconductor. In one embodiment the nanostructure is a nanoparticle. In one embodiment the nanoparticle is gold. In another embodiment the nanoparticle is silver. In another embodiment the charge accepting semiconductor is a metal oxide. In yet another embodiment the metal oxide is TiO₂. In yet another embodiment the metal oxide is ZnO. In one embodiment the dye is an organic dye.

In another aspect the invention relates to a plasmon enhanced solar photovoltaic cell. The photovoltaic cell includes a plurality of nanoparticles capable of plasmon resonance; a plurality of nanoparticles of charge accepting semiconductor in conduction with the nanoparticles capable of plasmon resonance; and a coating of sensitizer such as an organic dye, smaller band-gap semiconductor nanocrystals or quantum dots on the plurality of nanoparticles of charge accepting semiconductor. In one embodiment the nanoparticles of charge accepting semiconductor are sintered together. In another embodiment the photovoltaic cell includes a hole conductor or electrolyte in communication with the coating of sensitizer or dye. In another embodiment the photovoltaic cell further includes an electrode in communication with the hole conductor. In one embodiment the hole conductor is a polymeric hole semiconductor such as poly(phenylenevinylene) polymers (PPV).

In still yet another embodiment the invention relates to a method of making a plasmon enhanced material suitable for use in a photovoltaic cell. The steps include providing a nanostructure capable of plasmon resonance; providing a charge accepting semiconductor in conjunction with the nanostructure; sintering the charge accepting semiconductor; and coating the charge accepting semiconductor with a sensitizer.

### BRIEF DESCRIPTION OF THE DRAWINGS

These and other aspects of the invention may be better understood by reference to the following specification and drawings in which:

FIG. 1a-c are schematic diagrams of a nanocrystaline photovoltaic cell, such as a Gratzel cell, according to an embodiment of the present invention known to the prior art;

FIG. 2 illustrates the use of plasmon absorption enhancing structures in the TiO₂ matrix according to an embodiment of the present invention; and

FIG. 3 is an embodiment of a nanopatterned charge accepting semiconductor matrix in conjunction with a plasmon enhanced nanoparticle constructed in accordance with the invention.

### DETAILED DESCRIPTION OF A PREFERRED EMBODIMENT

In brief overview, in one embodiment of the present invention, a plasmon resonant material such as a nanoparticle of gold or silver is coated with a charge accepting semiconductor. In one embodiment the charge accepting semiconductor is a metal oxide such as TiO₂ or ZnO. These coated nanoparticles are then sintered together to form a structure that is composed of nanoparticles in contact with each other. In one embodiment the sintering may be accomplished using cold sintering, for example as developed by Dr. Sukant Tripathy at Konarka Technologies. A sensitizer such as a dye, a smaller band-gap semiconductor or quantum dots is then coated on the structure. Quantum dot particles include CdSₓ, Se₁₋ₓ, and ZnSₓSe₁₋ₓ. In one embodiment the dye is an organic dye. The result is a multilayered structure of plasmon resonant metal nanoparticles with shells of charge accepting semiconductor and a sensitizer.

The sensitizer and charge accepting semiconductor allow light to reach the plasmon resonant nanoparticle and excite a plasmon resonance at the interface of the nanoparticle. The electric field from the plasmon resonance extends through the charge accepting semiconductor to the sensitizer. The plasmon is resonant with the absorption band of the sensitizer. This causes the sensitizer to experience an enhanced field, thereby enhancing light absorption by the sensitizer so as to increase the efficiency of charge injection by the sensitizer.

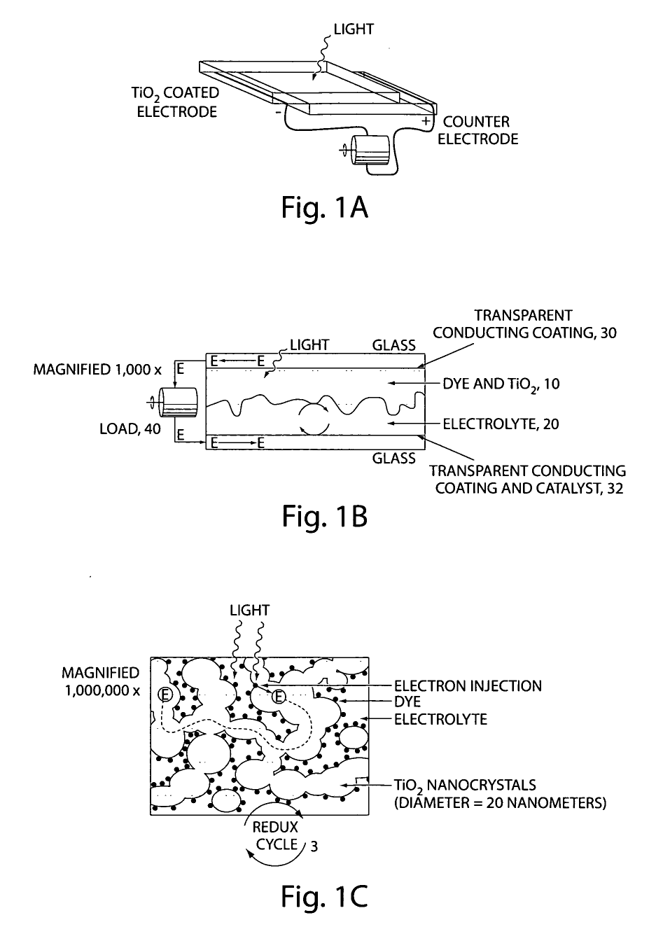

Referring to FIG. 1 again, the use of this enhanced material in a nanocrystal photovoltaic cell such as a Gratzel cell requires simply replacing the original sintered material with the plasmon resonance material (FIG. 1a). In this cell (FIG. 1b), the sintered, enhanced plasmon resonant charge accepting semiconductor coated with sensitizer 10 is placed in contact with a hole conductor such as an electrolyte (20) between two transparent electrodes 30, 32. A load 40 is then connected to transparent electrodes 30, 32.

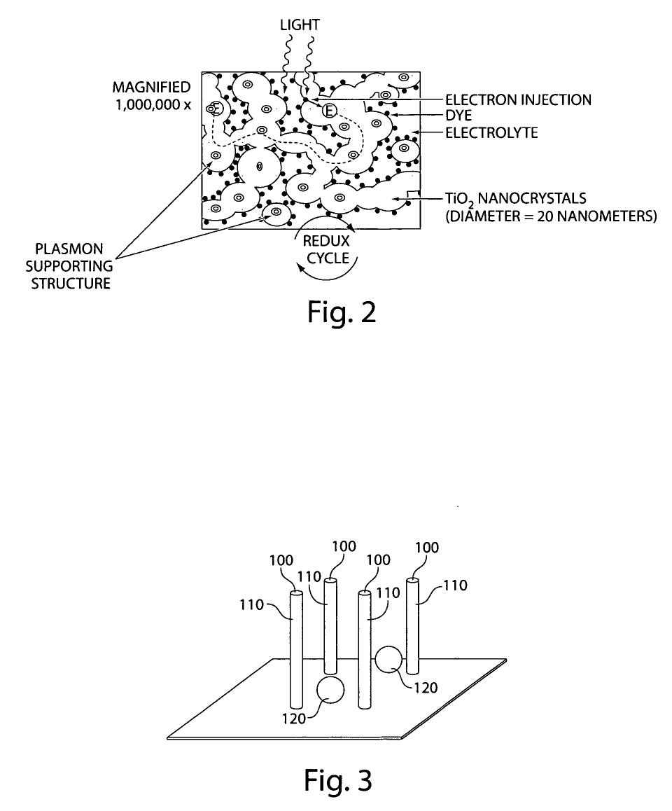

Referring to FIG. 2, in operation, when light is absorbed by the dye, an electron is released into the charge accepting semiconductor and makes its way to one of the electrodes 30. The presence of the plasmon resonant nanoparticles enhances the absorption of light by the sensitizer. To reduce the sensitizer (for example a dye), electrons are returned by way of the second electrode 32 to pass into the hole conductor (such as an electrolyte), which then returns the electrons to the sensitizer.

In one embodiment the plasmon resonant nanoparticle is a nanoparticle of gold. The gold nanoparticle is coated with TiO₂ and sintered to form an aggregate. The aggregated particles form protuberances having a diameter less than the wavelength of light. The aggregate is then coated with an organic dye. In one embodiment, the electrolyte is a solution of complexes of cobalt such as those described in Chem. Eur. J. 2003, 9, 3756 “An Alternative Efficient Redox Couple for the Dye-Sensitized Solar Cell” by Herve Nusbaumer, Shaik M. Zakeeruddin, Jacques-E. Moser, and Michael Graetzel, and other redox systems that are non-corrosive to the metallic nanostructure.

In other embodiments, the plasmon resonant nanostructure may be constructed of a shell of metal surrounded by a shell of charge accepting semiconductor. In addition, it is possible to construct the enhanced material by coating a charge accepting semiconductor such as metal oxide nanoparticle with a sensitizer such as an organic dye and placing it in contact with a plasmon resonant nanostructure. Additional embodiments may be fabricated such that the plasmon resonant nanostructures are an ordered array or randomized array of nanoprotrusions or nanoholes in a substrate. The protrusions or holes are sized such that they are less than the wavelength of light in height (protrusions) or diameter (holes). Additionally, the nanostructures may be formed as fibers having a diameter less than the wavelength of light needed to excite the plasmon resonance.

The nanostructures are then coated with a charge accepting semiconductor coating and coated with a sensitizer such as an organic dye (for example ruthenium dye). A hole conductor such as PPV is then deposited about the structures to provide a pathway for electrons to return back to the sensitizer.

Referring to FIG. 3, another embodiment of a nanopatterned includes an array of nanopatterned charge accepting semiconductor rods 100 coated with sensitizer 110. Within the array is located the plasmon resonant nanostructure 120 such as a nanoparticle.

The foregoing description has been limited to a few specific embodiments of the invention. It will be apparent, however, that variations and modifications can be made to the invention, with the attainment of some or all of the advantages of the invention. It is therefore the intent of the inventor to be limited only by the scope of the appended claims.

1. A plasmon enhanced particle suitable for use in a photovoltaic cell comprising:
a nanostructure capable of plasmon resonance;
a charge accepting semiconductor in conjunction with the nanostructure; and
a sensitizer coating the charge accepting semiconductor.

2. The plasmon enhanced particle of claim 1 wherein the nanostructure is a nanoparticle.

3. The plasmon enhanced particle of claim 2 wherein the nanoparticle is gold.

4. The plasmon enhanced particle of claim 2 wherein the nanoparticle is silver.

5. The plasmon enhanced particle of claim 1 wherein the charge accepting semiconductor is TiO₂.

6. The plasmon enhanced particle of claim 1 wherein the charge accepting semiconductor is ZnO.

7. The plasmon enhanced particle of claim 1 wherein the sensitizer is an organic dye.

8. A plasmon enhanced solar photovoltaic cell comprising:
a plurality of nanoparticles capable of plasmon resonance;
a plurality of nanoparticles of charge accepting semiconductor in conjunction with the nanoparticles capable of plasmon resonance, the nanoparticles of charge accepting semiconductor sintered together; and
a coating of sensitizer on the plurality of nanoparticles of charge accepting semiconductor.

9. The plasmon enhanced photovoltaic cell of claim 8 further comprising a hole conductor in communication with the coating of sensitizer.

10. The plasmon enhanced photovoltaic cell of claim 9 further comprising an electrode in communication with the hole conductor.

11. A method of making a plasmon enhanced material suitable for use in a photovoltaic cell comprising the steps of:
providing a nanostructure capable of plasmon resonance;
providing a charge accepting semiconductor in conjunction with the nanostructure;
sintering the charge accepting semiconductor; and
coating the charge accepting semiconductor with a sensitizer.

12. The method of claim 11 wherein the nanostructure is a nanoparticle.

13. The method of claim 12 wherein the nanoparticle is gold.

14. The method of claim 12 wherein the nanoparticle is silver.

15. The method of claim 11 wherein the charge accepting semiconductor is TiO₂.

16. The method of claim 11 wherein the charge accepting semiconductor is ZnO.

17. The method of claim 11 wherein the sensitizer is an organic dye.

18. The method of claim 11 wherein the sensitizer is an small band-gap semiconductor.

19. The method of claim 11 wherein the sensitizer is a quantum dot.
